(19) United States
(12) Patent Application Publication
(10) Pub. No.: US 2009/0185353 A1
(43) Pub. Date: Jul. 23, 2009

(54) MOUNTING APPARATUS FOR MOTHERBOARD

(75) Inventor: Zhan-Yang Li, Shenzhen City (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) Co.,LTD., Shenzhen City (CN); HON HAI PRECISION INDUSTRY CO., LTD., Tu-Cheng (TW)

(21) Appl. No.: 12/143,661

(22) Filed: Jun. 20, 2008

(30) Foreign Application Priority Data
Jan. 21, 2008 (CN) 200820300114.8

(51) Int. Cl. H05K 7/14

(52) U.S. Cl. 361/727

(57) ABSTRACT

A mounting assembly includes a motherboard with a plurality of mounting holes defined therein, a fixture, and a slide module for securing the motherboard in the fixture. The fixture includes a bottom panel and a plurality of mounting posts extending from the bottom panel. The mounting posts engage in the mounting holes of the motherboard. The slide module is slidably attached to the fixture between a release position spaced apart from the motherboard and a secure position securing the motherboard on the mounting posts of the bottom panel of the fixture.

### BACKGROUND

1. Technical Field

The present invention relates to mounting apparatuses, and more particularly to a mounting apparatus for a motherboard to be tested.

2. Description of Related Art

During testing of a motherboard, a mounting apparatus which includes a frame with a bottom panel, is usually provided to fix the motherboard. A plurality of openings is defined in the bottom panel. The motherboard is secured on the bottom panel of the frame by screws. Then the frame is placed on a test fixture, and test probes of the test fixture connect with corresponding electric points of the motherboard via the opening of the bottom panel. However, it is inconvenient and time-consuming to fix or detach the motherboard by installing or removing screws, especially when there are many motherboards to be tested.

What is needed, therefore, is a mounting apparatus for conveniently fixing or detaching a motherboard to be tested.

### BRIEF DESCRIPTION OF THE DRAWINGS

FIG. 1 is an exploded, isometric view of a motherboard and a mounting apparatus for the motherboard, the mounting apparatus including a fixture, a slide module, a pair of spring retainers, and a limiting member;

FIG. 2 is an enlarged view of an encircled portion 11 of FIG. 1;

FIG. 3 is a partially assembled view of FIG. 1, showing the slide module attached to the fixture at a release position;

FIG. 4 shows one of the spring retainers of FIG. 3 in a natural state; and

FIG. 5 shows the spring retainer of FIG. 4 in a retracted state;

FIG. 6 shows one of the spring retainers and the limiting member of FIG. 3 protruding at another side of the slide module; and

FIG. 7 is an assembled view of FIG. 1.

### DETAILED DESCRIPTION

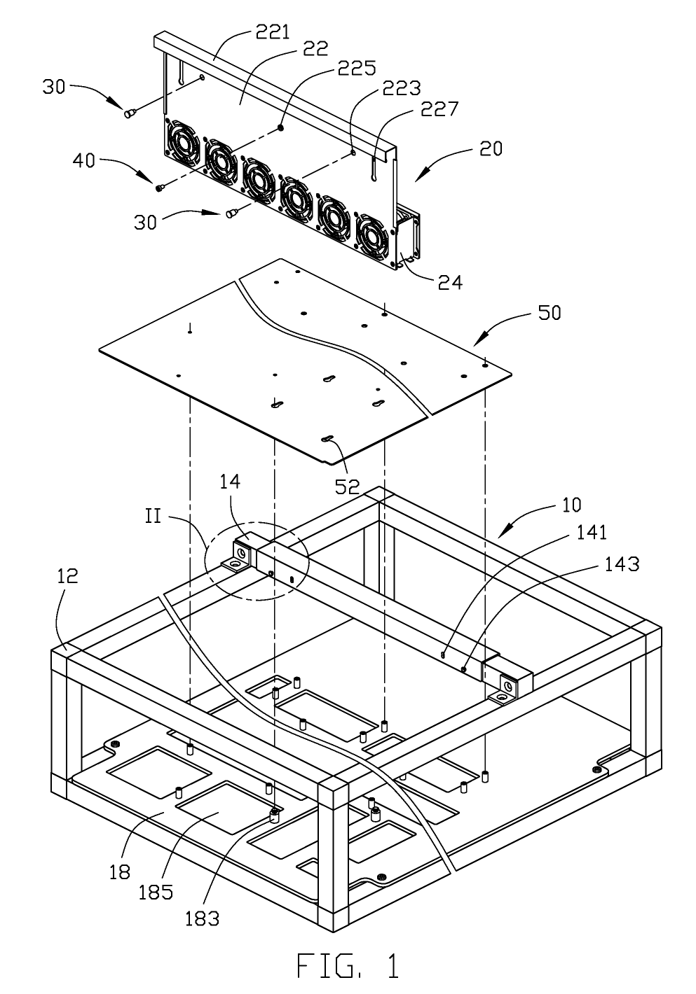

Referring to FIG. 1, a mounting apparatus in accordance with an exemplary embodiment of the present invention includes a fixture 10, a slide module 20, a pair of spring retainers 30, and a limiting member 40. The mounting apparatus is used to mount a motherboard 50 to be tested. The motherboard 50 includes a plurality of mounting holes 52. Each of the mounting holes 52 includes a first circular portion and a second circular portion bigger than the first circular portion.

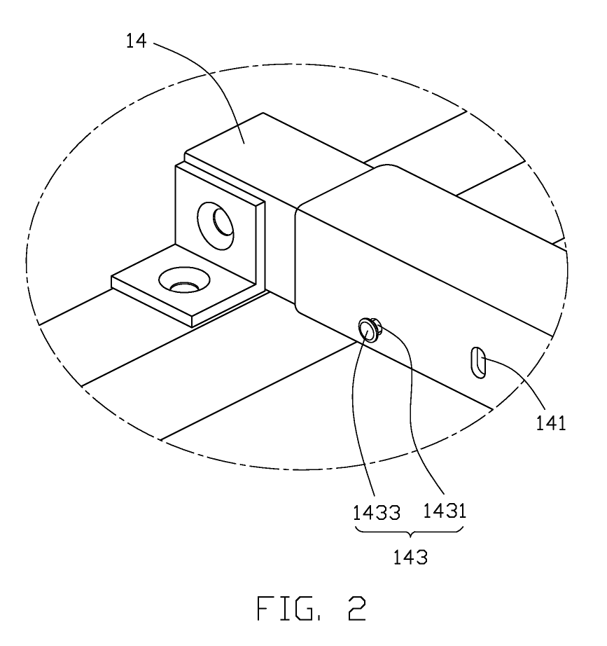

Referring to FIGS. 1 and 2, the fixture 10 includes a cuboid-shaped frame 12. The frame 12 includes twelve beams forming a cuboid-shaped space and a crossbeam 14 attached on two top parallel beams thereof. A pair of elongate limiting slots 141 is defined in the crossbeam 14. A pair of slide posts 143 protrudes from the crossbeam 14. Each of the slide posts 143 includes a neck 1431 extending from the crossbeam 14 and a cap 1433 at a distal end thereof. The frame 12 further includes a bottom panel 18 attached on four bottom beams thereof. A plurality of mounting posts 183 protrudes from the bottom panel 18 corresponding to the mounting holes 52 of the motherboard 50. A plurality of openings 185 is defined in the bottom panel 18.

The slide module 20 includes a side panel 22 and a fan module 24 attached on a lower backside of the side panel 22. A handle 221 extends from a top edge of the side panel 22. A pair of receiving holes 223 is defined in the side panel 22 corresponding to the spring retainers 30. A fixing post 225 with a screw hole for receiving the limiting member 40 protrudes from the side panel 22 at a central position lower than the receiving holes 223 of the side panel 22. A pair of elongated guide slots 227 is defined in the side panel 22. Each of the guide slots 227 includes a long narrow slide portion, and a wider circular entrance portion. The width of the sliding portion of the guide slot 227 is not less than that of the neck 1431 of the slide post 143 of the crossbeam 14 of the fixture 10 for allowing the neck 1431 sliding therein, but less than that of the cap 1433 of the slide post 143 of the crossbeam 14 for preventing the slide module 20 disengaging from the slide portion of the guide slot 227. The circular entrance portion of the guide slot 227 is wider than that of the cap 1433 of the slide post 143 for allowing the slide post 143 to engage in the guide slot 227.

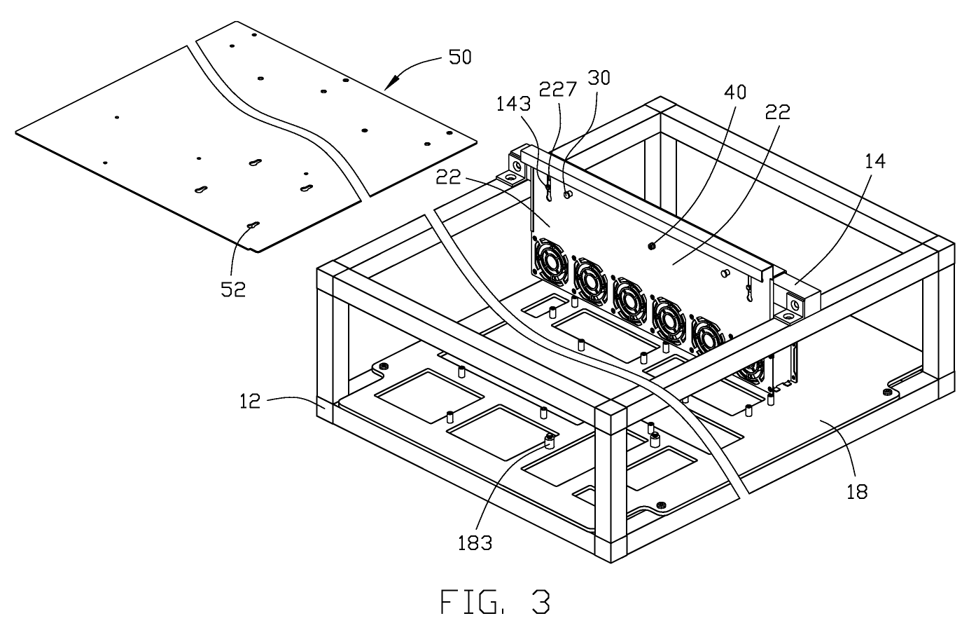

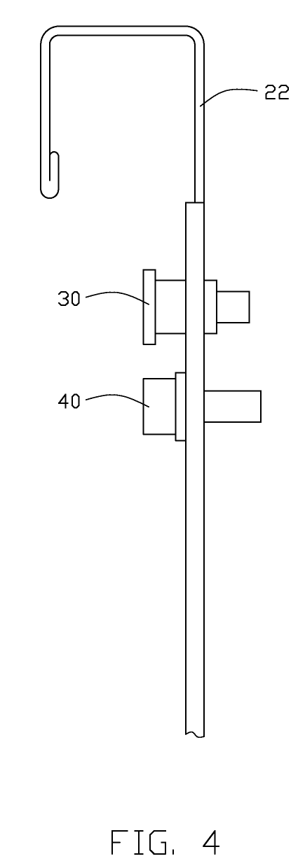

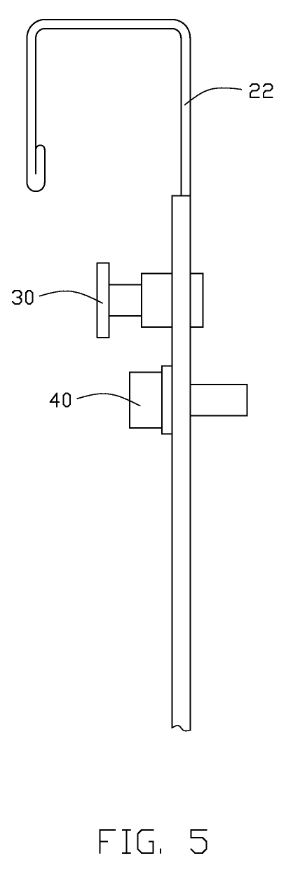

Referring to FIGS. 3-5, in assembly, the slide posts 143 of the fixture 10 engage in the slide portions of the guide slots 227 of the slide module 20 from the entrance portion of the guide slots 227 respectively. The spring retainers 30 engage in the receiving holes 223 of the slide module 20 respectively. A distal end of each of the spring members 30 protrudes when in a natural/released state (See FIG. 4), but retracts when in a pulled state (See FIG. 5).

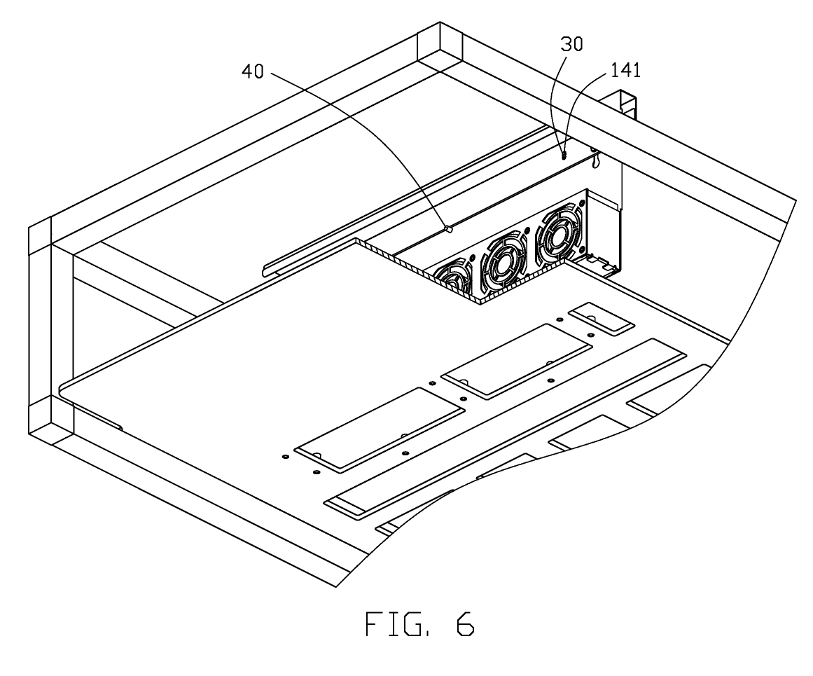

Referring to FIG. 6, the distal end of each of the spring members 30 inserts in a corresponding limiting slot 141 defined in the crossbeam 14 of the fixture 10 for restricting downward sliding of the slide module 20 at the release position. The limiting member 40 engages in the screw hole of the fixing post 225 of the slide module 20 and resists against the crossbeam 14 of the fixture 10 for restricting upward sliding of the slide module 20 at the release position.

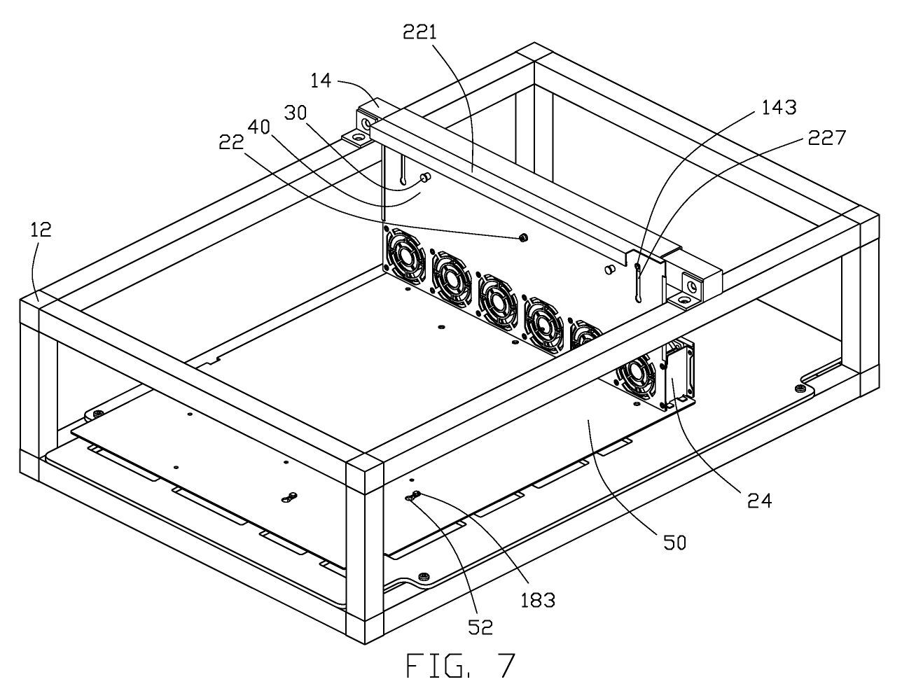

Referring to FIG. 7, the mounting posts 183 of the bottom panel 18 of the frame 12 engage in the second circular portion of the mounting holes 52 of the motherboard 50 respectively. Then the motherboard 50 is slid until the mounting posts 183 engage with the first circular portion of the mounting holes 52. The spring retainers 30 are pulled until distal ends thereof disengaging from the limiting slots 141 of the fixture 10. Then the slide module 20 is slid downward. The slide posts 143 reaches upper ends of the guide slots 227 after the slide module 20 slides to a secure position to secure the motherboard 50. The fan module 24 of the slide module 20 electrically connects with the motherboard 50 via connector plugs at the secure position. Thus, the motherboard 50 is secured on the bottom panel 18 of the frame 12.

In testing, test probes extend through the openings 185 of the bottom panel 18 of the frame 12 and connect with electric points of the motherboard 50 for testing electric signals of the motherboard 50.

In disassembly, the spring retainers 30 are pulled outward, and the handle 221 of the slide module 20 is pulled upward until the limiting member 40 resists against the crossbeam 14 of the frame 20. Then the spring retainers 30 are released to their natural state and engage in the limiting slots 141 of the crossbeam 14 of the frame 12. The slide module 20 is slid from the secure position to the release position to release the motherboard 50. The motherboard 50 is slid until the mounting posts 183 engaging with the second portion of the mounting holes 52 and removed from the bottom panel 18 of the fixture 10. Another motherboard to be tested can be installed in the fixture 10 when the slide module 20 is at the release position.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A mounting apparatus comprising:
a fixture comprising a bottom panel and a crossbeam, a limiting slot being defined in the crossbeam;
a slide module attached to the crossbeam, the slide module slidable between a release position, where the slide module is spaced from the bottom panel of the fixture to unlock a motherboard, and a secure position, where the slide module presses the bottom panel of the fixture and is capable of securing a motherboard; and
a spring member engages with the limiting slot of the crossbeam of the fixture for preventing the slide module sliding from the release position to the secure position.

2. The mounting apparatus as described in claim 1, wherein the slide module is attached to the crossbeam in a first direction that is parallel the bottom panel and slidable along the crossbeam in a second direction that is perpendicular to the bottom panel.

3. The mounting apparatus as described in claim 1, wherein a slide post extends from the crossbeam, a guide slot is defined in the slide module for allowing the slide post sliding therein.

4. The mounting apparatus as described in claim 3, wherein the slide post comprises a neck and a cap at a distal end thereof, the guide slot comprises a slide portion engaging with the neck of the slide post and an entrance portion for allowing the cap of the slide post engaging in or disengaging from the guide slot.

5. The mounting apparatus as described in claim 1, wherein a distal end of the spring member engages in the limiting slot of the crossbeam of the fixture at a natural state, and disengages from the limiting slot of the crossbeam of the fixture at a pulled state for allowing the sliding module sliding from the release position to the secure position.

6. The mounting apparatus as described in claim 1, wherein a limiting member is attached to the sliding module and resists against the crossbeam of the fixture at the release position.

7. The mounting apparatus as described in claim 1, wherein the fixture comprises a pair of top beams, the crossbeam is attached to the top beams.

8. An apparatus comprising:
a motherboard with a plurality of mounting holes defined therein;
a fixture comprising a bottom panel, a crossbeam and a plurality of mounting posts extending from the bottom panel engaging with mounting holes of the motherboard; and
a slide module slidably attached to the crossbeam; the slide module is movable between a release position and a secure position, the release position comprises the slide module being spaced from the motherboard and the secure position comprises the slide module securing the motherboard on the mounting posts of the bottom panel of the fixture.

9. The apparatus as described in claim 8, wherein the fixture comprises a frame, the frame comprises two top beams and the crossbeam is attached to the top beams, the slide module is slidably attached to the crossbeam

10. The apparatus as described in claim 9, wherein the crossbeam is perpendicularly attached on the top beams, the slide module is slidable along a direction perpendicular to the bottom panel of the frame.

11. The apparatus as described in claim 10, wherein a slide post extends from the crossbeam, a guide slot is defined in the slide module for allowing the slide post sliding therein.

12. The apparatus as described in claim 11, wherein the slide post comprises a neck and a cap at a distal end thereof, the guide slot comprises a slide portion engaging with the neck of the slide post and an entrance portion for allowing the cap of the slide post engaging in or disengaging from the guide slot.

13. The apparatus as described in claim 11, wherein a limiting slot is defined in the crossbeam, a spring member engages with the limiting slot for preventing the slide module sliding from the release position to the secure position.

14. The apparatus as described in claim 13, wherein a distal end of the spring member engages in the limiting slot of the crossbeam of the fixture at a natural state, and disengages from the limiting slot of the crossbeam of the fixture at a pulled state for allowing the sliding module sliding from the release position to the secure position.

15. The apparatus as described in claim 14, wherein a limiting member is attached to the sliding module and engages the crossbeam of the fixture when the sliding member is in the release position.

16. An apparatus comprising:
a motherboard to be tested;
a fixture for accommodating the motherboard therein;
a slide module attached to the fixture capable of sliding to a secure position, wherein the secured position comprises the motherboard be electrically connected to the slide module as well as being secured by the slide module.

17. The apparatus as described in claim 16, wherein the slide module slides to the secure position from a release position, wherein the release position comprises of a space between the slide module and the motherboard.

18. The apparatus as described in claim 17, wherein the fixture comprises a bottom panel and a crossbeam above the bottom panel, the slide module is slidably attached to the crossbeam and secures the motherboard on the bottom panel when it slides to the secure position.

19. The apparatus as described in claim 18, wherein a limiting slot is defined in the crossbeam and a spring retainer engages with the limiting slot for preventing the slide module sliding from the release position to the secure position.

20. The apparatus as described in claim 19, wherein a limiting post is mounted to the slide module and engages with the crossbeam when the spring retainer is aligned with the limiting slot.
